(19) United States
(12) Patent Application Publication
(10) Pub. No.: US 2025/0351555 A1
(43) Pub. Date: Nov. 13, 2025

(54) SEMICONDUCTOR DEVICE

(71) Applicant: FUJI ELECTRIC CO., LTD., Kanagawa (JP)

(72) Inventors: Yosuke SAKURAI, Azumino-city (JP); Tatsuhiko FUJIHIRA, Matsumoto-city (JP); Tatsuya NAITO, Matsumoto-city (JP); Masahiro SASAKI, Azumino-city (JP); Norihiro KOMIYAMA, Matsumoto-city (JP); Nao SUGANUMA, Hachioji-city (JP)

(21) Appl. No.: 19/277,306

(22) Filed: Jul. 22, 2025

Related U.S. Application Data
(63) Continuation of application No. PCT/JP2024/023576, filed on Jun. 28, 2024.

(30) Foreign Application Priority Data
Aug. 22, 2023 (JP) 2023-135040

(51) Int. Cl. H10D 84/80; H10D 1/40; H10D 8/00; H10D 12/00; H10D 62/10

(52) U.S. Cl. CPC H10D 84/811; H10D 1/40; H10D 8/422; H10D 12/415; H10D 12/481; H10D 62/103; H10D 62/126

(57) ABSTRACT

There is provided a semiconductor device which includes a plurality of transistor regions; a gate pad provided above a semiconductor substrate; a plurality of gate wiring portions each of which corresponds to each of the plurality of transistor regions; and a plurality of wiring resistance portions each of which is electrically connected to the gate pad and corresponds to each of the plurality of gate wiring portions. The plurality of gate wiring portions may include a gate metal layer provided above the semiconductor substrate and a gate runner provided below the gate metal layer. A built-in resistance portion may be electrically connected between the gate pad and the plurality of gate wiring portions.

The contents of the following patent application(s) are incorporated herein by reference: NO. 2023-135040 filed in JP on Aug. 22, 2023, and NO. PCT/JP2024/023576 filed in WO on Jun. 28, 2024.

### BACKGROUND

### 1. Technical Field

The present invention relates to a semiconductor device.

### 2. Related Art

Patent document 1 describes a semiconductor device in which “a resistance value of a built-in resistance which is distant from a gate pad 12 is greater than a resistance value of a built-in resistance which is close to the gate pad 12.”

### RELATED ART DOCUMENTS

### Patent Documents

Patent Document 1: Japanese Patent Application Publication No. 2010-98250
Patent Document 2: Japanese Patent No. 6874443
Patent Document 3: Japanese Patent No. 6187697
Patent Document 4: Japanese Patent No. 5493840

### BRIEF DESCRIPTION OF THE DRAWINGS

FIG. 1A illustrates an example of an upper surface of a semiconductor device 100.

FIG. 1B illustrates an example of the upper surface of the semiconductor device 100.

FIG. 1C illustrates an example of a cross section a-a′ of the semiconductor device 100.

FIG. 2A illustrates an example of the upper surface of the semiconductor device 100.

FIG. 2B illustrates an example of an enlarged view of the upper surface of the semiconductor device 100.

FIG. 2C illustrates an example of a cross section b-b′ of the semiconductor device 100.

FIG. 2D illustrates an example of a cross section c-c′ of the semiconductor device 100.

FIG. 3 illustrates an example of an upper surface of a resistance measurement pad of the present example.

FIG. 4A illustrates a modification example of the upper surface of the semiconductor device 100.

FIG. 4B illustrates a modification example of the upper surface of the semiconductor device 100.

FIG. 5A illustrates a modification example of the upper surface of the semiconductor device 100.

FIG. 5B illustrates an example of a cross section d-d′ of the semiconductor device 100.

### DESCRIPTION OF EXEMPLARY EMBODIMENTS

The present invention will be described below through embodiments of the invention, but the following embodiments do not limit the invention according to the claims. In addition, not all combinations of features described in the embodiments are essential to a solution of the invention.

In the present specification, one side in a direction parallel to a depth direction of a semiconductor substrate is referred to as “upper” and another side is referred to as “lower”. One surface of two principal surfaces of a substrate, a layer or another member is referred to as an upper surface, and another surface is referred to as a lower surface. “Upper” and “lower” directions are not limited to a direction of gravity, or a direction in implementation of a semiconductor device.

In the present specification, technical matters may be described by using orthogonal coordinate axes of an X-axis, a Y-axis, and a Z-axis. The orthogonal coordinate axes merely specify relative positions of components, and do not limit a particular direction. For example, the Z-axis is not limited to indicate a height direction with respect to the ground. It is to be noted that a +Z-axis direction and a −Z-axis direction are directions opposite to each other. When the Z-axis direction is described without describing a sign, it means that the direction is parallel to the +Z-axis and the −Z-axis.

In the present specification, orthogonal axes parallel to the upper surface and the lower surface of the semiconductor substrate are referred to as the X-axis and the Y-axis. In addition, an axis perpendicular to the upper surface and the lower surface of the semiconductor substrate is referred to as the Z-axis. In the present specification, the direction of the Z-axis may be referred to as the depth direction. In addition, in the present specification, a direction parallel to the upper surface and the lower surface of the semiconductor substrate may be referred to as a horizontal direction, including an X-axis direction and a Y-axis direction.

In the present specification, a description of a P+ type or an N+ type means a higher doping concentration than that of the P type or the N type, and a description of a P− type or an N-type means a lower doping concentration than that of the P type or the N type.

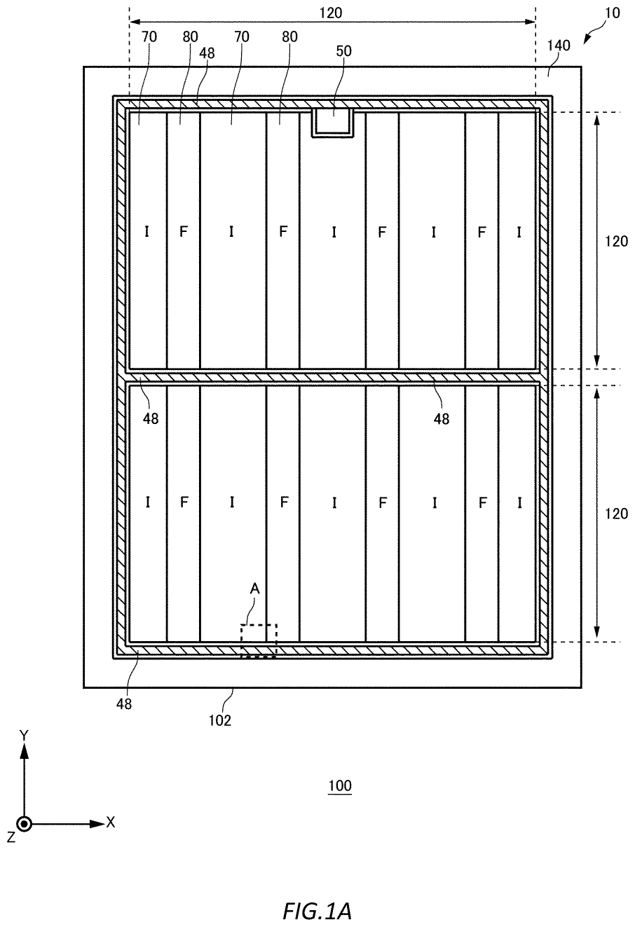

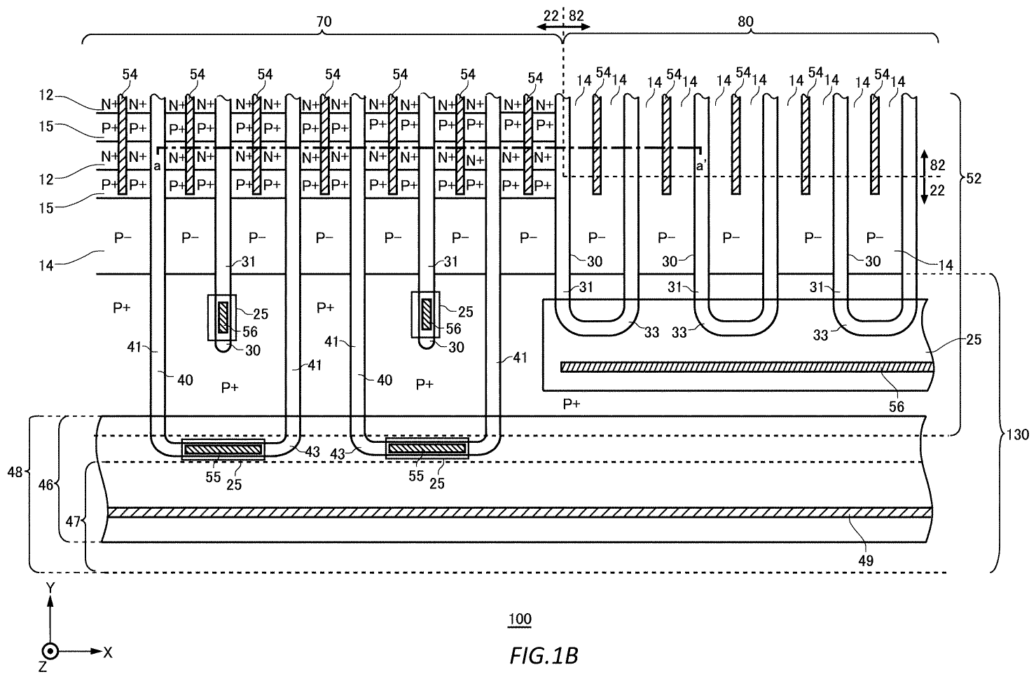

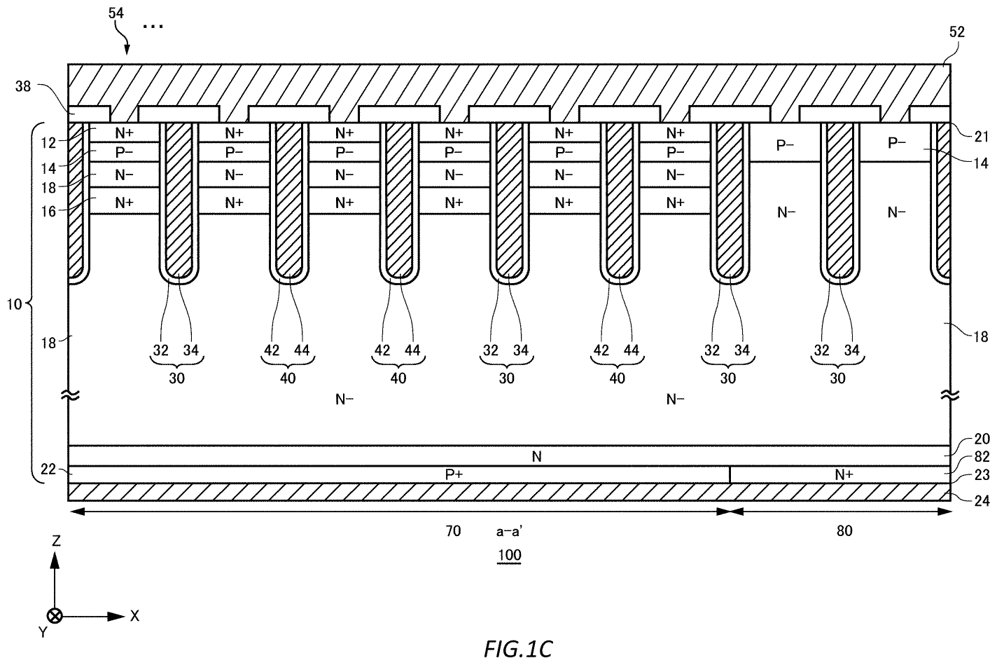

FIG. 1A illustrates an example of an upper surface of a semiconductor device 100. In the present example, only some members of the semiconductor device 100 are illustrated and some members are omitted. The semiconductor device 100 may be an example of a single semiconductor chip, or an example of a semiconductor module including a plurality of semiconductor chips.

A semiconductor substrate 10 has end sides 102 in a top view. The semiconductor substrate 10 in the present example includes two sets of end sides 102 facing each other in the top view. In the present example, the X-axis and the Y-axis are parallel to any of the end sides 102. The semiconductor substrate 10 is made of silicon. The semiconductor substrate 10 may be a wide bandgap semiconductor such as gallium nitride and silicon carbide.

The semiconductor substrate 10 is provided with a plurality of transistor regions 120. Each transistor region 120 of the plurality of transistor regions 120 is a region through which a main current flows in the depth direction between a front surface 21 and a back surface 23 of the semiconductor substrate 10 when the semiconductor device 100 is operated. The front surface 21 and the back surface 23 will be described below. Although an emitter electrode is provided above the transistor region 120, it is omitted in this figure.

The transistor region 120 is provided with at least one of a transistor portion 70 including a transistor element such as an IGBT, or a diode portion 80 including a diode element such as a freewheeling diode (FWD). In the example of FIG. 1A, the transistor portion 70 and the diode portion 80 are alternately arranged along a predetermined array direction, i.e., the X-axis direction in the present example, on the front surface 21 of the semiconductor substrate 10. In another example, the transistor region 120 may only be provided with any one of the transistor portion 70 or the diode portion 80.

In the present example, a region where the transistor portion 70 is arranged is denoted by a symbol “I”, and a region where the diode portion 80 is arranged is denoted by a symbol “F”. The transistor portion 70 and the diode portion 80 may each have a longitudinal length in an extension direction. That is, a length of the transistor portion 70 in the Y-axis direction is larger than its width in the X-axis direction. Similarly, a length of the diode portion 80 in the Y-axis direction is larger than its width in the X-axis direction. The extension directions of the transistor portion 70 and the diode portion 80 and a longitudinal direction of each trench portion may be the same.

The transistor portion 70 is a region obtained by projecting a collector region 22 provided on a back surface side of the semiconductor substrate 10 onto the upper surface of the semiconductor substrate 10. The collector region 22 will be described below. The transistor portion 70 includes a transistor such as an IGBT. In the present example, the transistor portion 70 is an IGBT. The transistor portion 70 may be another transistor such as a MOSFET. The transistor portion 70 may be a transistor having a planar structure or a trench structure.

The diode portion 80 is a region obtained by projecting a cathode region 82 provided on the back surface 23 side of the semiconductor substrate 10 onto the upper surface of the semiconductor substrate 10. The cathode region 82 will be described below. On the back surface 23 of the semiconductor substrate 10, the collector region 22 of the P+ type may be provided in a region other than the cathode region 82.

The semiconductor device 100 may include one or more pads above the semiconductor substrate 10. The semiconductor device 100 in the present example includes a gate pad 50. The semiconductor device 100 may include a pad such as an anode pad and a cathode pad. In the present example, each pad is arranged near any of the end sides 102. The phrase “near any of the end sides 102” refers to a region between any of the end sides 102 and a corresponding transistor region 120 in the top view. In implementation of the semiconductor device 100, each pad may be connected to an external circuit via wiring such as a wire. In addition, each pad may not be arranged near the end sides 102.

The gate pad 50 is applied with a gate potential. The gate pad 50 is electrically connected to a gate conductive portion of a gate trench portion in each of the transistor regions 120 via a plurality of gate wiring portions 48. In FIG. 1A, the gate wiring portions 48 are hatched with diagonal lines.

Each of the gate wiring portions 48 may be composed of any one of a gate metal layer 47 or a gate runner 46 described below, or composed of an appropriate combination of both of them. A configuration and arrangement of the gate wiring portions 48 and the transistor regions 120 will be described below.

An edge termination structure portion 140 is provided on the front surface 21 of the semiconductor substrate 10. The edge termination structure portion 140 is provided between each of the transistor regions 120 and the end sides 102 in the top view. The edge termination structure portion 140 in the present example is arranged between the gate wiring portion 48 and the end sides 102. The edge termination structure portion 140 reduces electric field strength on the front surface 21 side of the semiconductor substrate 10. The edge termination structure portion 140 may include at least one of a guard ring, a field plate, or a RESURF which annularly surrounds the transistor region 120.

FIG. 1B illustrates an example of the upper surface of the semiconductor device 100. FIG. 1B is an enlarged view of a region indicated as A in FIG. 1A. FIG. 1B illustrates an area near a negative-side end portion in the Y-axis direction in one of the plurality of transistor regions 120. The semiconductor device 100 includes the semiconductor substrate 10 including the transistor portion 70 with the transistor element such as an IGBT, and the diode portion 80 with the diode element such as a freewheeling diode (FWD).

The semiconductor device 100 of the present example includes the gate trench portion 40, a dummy trench portion 30, a well region 130, an emitter region 12, a base region 14, and a contact region 15 provided inside a front surface side of the semiconductor substrate 10. Each of the gate trench portion 40 and the dummy trench portion 30 is an example of the trench portion.

In addition, the semiconductor device 100 of the present example includes the gate metal layer 47 and an emitter electrode 52 which are provided above the front surface of the semiconductor substrate 10. The emitter electrode 52 is an example of a front surface side electrode. The gate metal layer 47 and the emitter electrode 52 are electrically insulated.

Although an interlayer dielectric film is provided between each of the emitter electrode 52 and the gate metal layer 47, and the front surface of the semiconductor substrate 10, it is omitted in FIG. 1B. In the interlayer dielectric film of the present example, contact holes 49, 54, and 56 are provided to penetrate through the interlayer dielectric film. In FIG. 1B, each contact hole is hatched with diagonal lines.

The emitter electrode 52 is provided above the gate trench portion 40, the dummy trench portion 30, the well region 130, the emitter region 12, the base region 14, and the contact region 15. The emitter electrode 52 is electrically connected to the emitter region 12, the base region 14, and the contact region 15 on the front surface of the semiconductor substrate 10 through the contact holes 54.

In addition, the emitter electrode 52 is connected to a dummy conductive portion in the dummy trench portion 30 through the contact hole 56. Between the emitter electrode 52 and the dummy conductive portion, a connection portion 25 formed of a conductive material such as polysilicon doped with an impurity may be provided. The connection portion 25 is provided on the front surface of the semiconductor substrate 10 via a dielectric film such as the interlayer dielectric film and a dummy dielectric film of the dummy trench portion 30.

The gate runner 46 is, in the front surface of the semiconductor substrate 10, connected to the gate conductive portion of the gate trench portion 40 through the contact hole 55. The gate runner 46 is electrically connected to the gate metal layer 47 via the contact hole 49. The gate runner 46 is not electrically connected to the dummy conductive portion in the dummy trench portion 30 and the emitter electrode 52.

The gate runner 46 and the emitter electrode 52 are electrically separated by an insulator such as the interlayer dielectric film and an oxide film. The gate runner 46 of the present example is provided from a position below the contact hole 49 to an edge portion, i.e., an end portion in the Y-axis direction, of the gate trench portion 40. At the edge portion of the gate trench portion 40, the gate conductive portion is exposed to the front surface of the semiconductor substrate 10, and is connected to the gate runner 46.

The emitter electrode 52 is formed of a conductive material containing metal. For example, it is formed of aluminum or an aluminum-silicon alloy. The emitter electrode 52 may include a barrier metal formed of titanium, titanium compound, and the like under the region formed of aluminum and the like.

The emitter electrode 52 may also have a plug formed of tungsten and the like in the contact hole. The emitter electrode 52 may have a barrier metal on a side in contact with the semiconductor substrate 10 and have tungsten embedded to be in contact with the barrier metal, and may be formed of aluminum and the like on tungsten.

The well region 130 extends to an outside of the gate runner 46 to overlap an outer peripheral region, and is annularly provided in the top view. The well region 130 also extends in the transistor region 120 inside the gate runner 46 with a predetermined width, and is annularly provided in the top view. The well region 130 in the present example is provided in a range farther away from an end portion of the contact hole 54 in the Y-axis direction toward a gate runner 46 side. The well region 130 is a region of a second conductivity type with a higher doping concentration than the base region 14. The doping concentration of the well region 130 may be the same as, or lower than, a doping concentration of the contact region 15. The gate runner 46 is electrically insulated from the well region 130.

In the present example, the base region 14 is a P− type, and the well region 130 is the P+ type. In addition, the well region 130 is formed from the front surface of the semiconductor substrate to a position deeper than a lower end of the base region 14. The base region 14 is provided in contact with the well region 130 in the transistor portion 70 and the diode portion 80. The well region 130 is electrically connected to the emitter electrode 52.

Each of the transistor portion 70 and the diode portion 80 has a plurality of trench portions arrayed in the array direction. In the transistor portion 70 of the present example, one or more gate trench portions 40 and one or more dummy trench portions 30 are alternately provided along the array direction. In the diode portion 80 in the present example, the plurality of dummy trench portions 30 are provided along the array direction.

In the present example, the array direction of the trench portions is the X-axis direction, and the extension direction perpendicular to the array direction is the Y-axis direction. The gate trench portion 40 of the present example may have two extension parts 41 extending along the extension direction, i.e., parts of the trench which are linear along the extension direction, and a connection part 43 connecting the two extension parts 41.

At least a part of the connection part 43 may be provided in a curved shape in the top view. End portions of the two extension parts 41 in the Y-axis direction are connected by the connection part 43, which is connected to the gate runner 46, so that the gate trench portion 40 functions as a gate electrode. On the other hand, by forming the connection part 43 into the curved shape, electric field strength at the end portions can be reduced, in comparison with a case where the extension parts 41 makes a termination.

In the transistor portion 70, the dummy trench portion 30 is provided between the respective extension parts 41 of the gate trench portion 40. Although one dummy trench portion 30 is provided between the respective extension parts 41 in the example of FIG. 1B, two or more dummy trench portions 30 may be provided.

In addition, between the respective extension parts 41, the dummy trench portion 30 may not be provided, and the gate trench portion 40 may be provided. With such a structure, the electron current from the emitter region 12 can be increased, so that an on-voltage is reduced.

The dummy trench portion 30 may have a linear shape extending in the extension direction, and may have extension parts 31 and a connection part 33, similarly to the gate trench portion 40. The semiconductor device 100 illustrated in FIG. 1B includes the dummy trench portion 30 in a U-shape with the connection part 33, and the dummy trench portion 30 in a linear shape without the connection part 33. The semiconductor device 100 may be configured to include only the dummy trench portion 30 with the connection part 33.

A diffusion depth of the well region 130 may be deeper than the depth of the gate trench portion 40 and the dummy trench portion 30. The end portions in the Y-axis direction of the gate trench portion 40 and the dummy trench portion 30 are provided in the well region 130 in the top view. That is, at the end portion of each trench portion in the Y-axis direction, a bottom portion of each trench portion in the depth direction (a positive side in the Z-axis direction) is covered with the well region 130. With this configuration, the electric field strength on the bottom portion of each trench portion can be reduced.

A mesa portion is provided between the respective trench portions in the array direction. The mesa portion refers to a region sandwiched between the trench portions inside the semiconductor substrate 10. As an example, a depth position of the mesa portion is from the front surface of the semiconductor substrate to a lower end of the trench portion.

The mesa portion of the present example is sandwiched between the adjacent trench portions in the X-axis direction and extends in the extension direction i.e., the Y-axis direction, along the trench in the front surface of the semiconductor substrate 10.

Each mesa portion is provided with the base region 14. In each mesa portion, at least one of the emitter region 12 of a first conductivity type or the contact region 15 of the second conductivity type may be provided in a region sandwiched between the base regions 14 in the top view. In the present example, the emitter region 12 is the N+ type, and the contact region 15 is the P+ type. The emitter region 12 and the contact region 15 may be provided between the base region 14 and the front surface of the semiconductor substrate 10 in the depth direction. As an example, the dopant of the emitter region 12 includes arsenic (As), phosphorus (P), antimony (Sb), and the like.

The mesa portion of the transistor portion 70 includes the emitter region 12 exposed at the front surface of the semiconductor substrate 10. The emitter region 12 is provided in contact with the gate trench portion 40. The mesa portion in contact with the gate trench portion 40 is provided with the contact region 15 exposed at the front surface of the semiconductor substrate 10.

Each of the contact region 15 and the emitter region 12 in the mesa portion is provided from one trench portion to another trench portion in the X-axis direction. As an example, the contact region 15 and the emitter region 12 in the mesa portion are alternately arranged along the extension direction of the trench portion i.e., the Y-axis direction.

In another example, the contact region 15 and the emitter region 12 in the mesa portion may be provided in a striped pattern along the extension direction of the trench portion i.e., the Y-axis direction. For example, the emitter region 12 is provided in a region in contact with the trench portion, and the contact region 15 is provided in a region sandwiched between the emitter regions 12.

The emitter region 12 is not provided in the mesa portion of the diode portion 80. An upper surface of the mesa portion of the diode portion 80 may be provided with the base region 14. The base region 14 may be arranged in the entire mesa portion of the diode portion 80. The base region 14 of the diode portion 80 operates as an anode.

The contact hole 54 is provided above each mesa portion. The contact hole 54 is arranged in a region sandwiched between the base regions 14 in its extension direction i.e., Y-axis direction. The contact hole 54 in the present example is provided above respective regions of the contact region 15, the base region 14, and the emitter region 12. The contact hole 54 may be arranged at the center of the mesa portion in the array direction i.e., the X-axis direction.

In the diode portion 80, a region adjacent to the back surface of the semiconductor substrate is provided with a cathode region 82 of an N+ type. In the back surface of the semiconductor substrate, a region in which the cathode region 82 is not provided may be provided with the collector region 22 of the P+ type. In FIG. 1B, a boundary between the cathode region 82 and the collector region 22 is indicated by a dotted line.

The boundary between the collector region 22 and the cathode region 82 is a boundary between the transistor portion 70 and the diode portion 80. That is, in the present example, the transistor portion 70 is a region where the collector region 22 provided in the back surface side of the semiconductor substrate 10 is projected onto the upper surface of the semiconductor substrate 10. In addition, the diode portion 80 is a region where the cathode region 82 provided in the back surface of the semiconductor substrate 10 is projected onto the upper surface of the semiconductor substrate 10.

FIG. 1C illustrates an example of a cross section a-a′ in FIG. 1B. The cross section a-a′ is an XZ plane which passes through the emitter region 12 in the transistor portion 70. The semiconductor device 100 of the present example includes, in the cross section a-a′, the semiconductor substrate 10 which includes the emitter region 12, the base region 14, an accumulation region 16, a drift region 18, a buffer region 20, the collector region 22, and the cathode region 82, an interlayer dielectric film 38, the emitter electrode 52, and a collector electrode 24. The collector electrode 24 is an example of a back-surface-side metal layer provided in contact with the back surface 23 of the semiconductor substrate 10.

The drift region 18 is a region of the first conductivity type which is provided in the semiconductor substrate 10. The drift region 18 of the present example is of the N− type, as an example. The drift region 18 may be a region in the semiconductor substrate 10 which has remained without other doping regions formed. That is, a doping concentration of the drift region 18 may be a doping concentration of the semiconductor substrate 10.

The accumulation region 16 is a region of the first conductivity type provided below the base region 14 in the semiconductor substrate 10. A doping concentration of the accumulation region 16 is higher than the doping concentration of the drift region 18. The accumulation region 16 in the present example is of the N+ type, as an example.

The accumulation region 16 may be provided in the transistor portion 70, and may not be provided in the diode portion 80. The accumulation region 16 may be provided in both the transistor portion 70 and the diode portion 80. Providing the accumulation region 16 can increase a carrier injection enhancement effect (IE effect) to reduce an on-voltage of the transistor portion 70.

The buffer region 20 of the first conductivity type may be provided below the drift region 18. The buffer region 20 of the present example is of the N type. A doping concentration of the buffer region 20 is higher than the doping concentration of the drift region 18. The buffer region 20 may function as a field stop layer configured to prevent a depletion layer expanding from a lower surface side of the base region 14 from reaching the collector region 22 and the cathode region 82.

In the transistor portion 70, the collector region 22 is provided below the buffer region 20. The collector region 22 may be provided in contact with the cathode region 82 in the back surface 23.

In the diode portion 80, the cathode region 82 is provided below the buffer region 20. The cathode region 82 may be provided at a same depth of that of the collector region 22 of the transistor portion 70. The diode portion 80 may function as a freewheeling diode (FWD) which allows the freewheeling current to flow in the reverse direction when the transistor portion 70 is turned off.

The collector electrode 24 is formed on the back surface 23 of the semiconductor substrate 10. The collector electrode 24 is formed of a conductive material such as metal. The collector electrode 24 may be formed of the same conductive material as that of the emitter electrode 52, or may be formed of a different conductive material.

The gate trench portion 40 includes a gate trench, a gate dielectric film 42, and a gate conductive portion 44 which are formed at the front surface 21. The gate dielectric film 42 is formed to cover an inner wall of the gate trench. The gate dielectric film 42 may be formed by oxidizing or nitriding a semiconductor on the inner wall of the gate trench. The gate conductive portion 44 is formed inside the gate dielectric film 42 within the gate trench. The gate dielectric film 42 insulates the gate conductive portion 44 from the semiconductor substrate 10. The gate conductive portion 44 is formed of a conductive material such as polysilicon. The gate trench portion 40 is covered with the interlayer dielectric film 38 on the front surface 21.

The gate conductive portion 44 includes, in the depth direction of the semiconductor substrate 10, a region facing the adjacent base region 14, with the gate dielectric film 42 being sandwiched therebetween. When a predetermined voltage is applied to the gate conductive portion 44, a channel with an electron inversion layer is formed in a surface layer of an interface of the base region 14 which is in contact with the gate trench.

The dummy trench portion 30 may have the same structure as that of the gate trench portion 40. The dummy trench portion 30 includes a dummy trench, a dummy dielectric film 32, and a dummy conductive portion 34 which are formed on the front surface 21 side. The dummy dielectric film 32 is formed to cover an inner wall of the dummy trench. The dummy conductive portion 34 is formed within the dummy trench, and is formed inside the dummy dielectric film 32. The dummy dielectric film 32 insulates the dummy conductive portion 34 from the semiconductor substrate 10. The dummy trench portion 30 is covered with the interlayer dielectric film 38 on the front surface 21.

The interlayer dielectric film 38 is provided on the front surface 21. The emitter electrode 52 is provided above the interlayer dielectric film 38. The interlayer dielectric film 38 may be provided with one or more trench contact portions to electrically connect the emitter electrode 52 to the semiconductor substrate 10. Similarly, the contact hole 49, the contact hole 55, and the contact hole 56 may include a trench contact portion provided to penetrate the interlayer dielectric film 38.

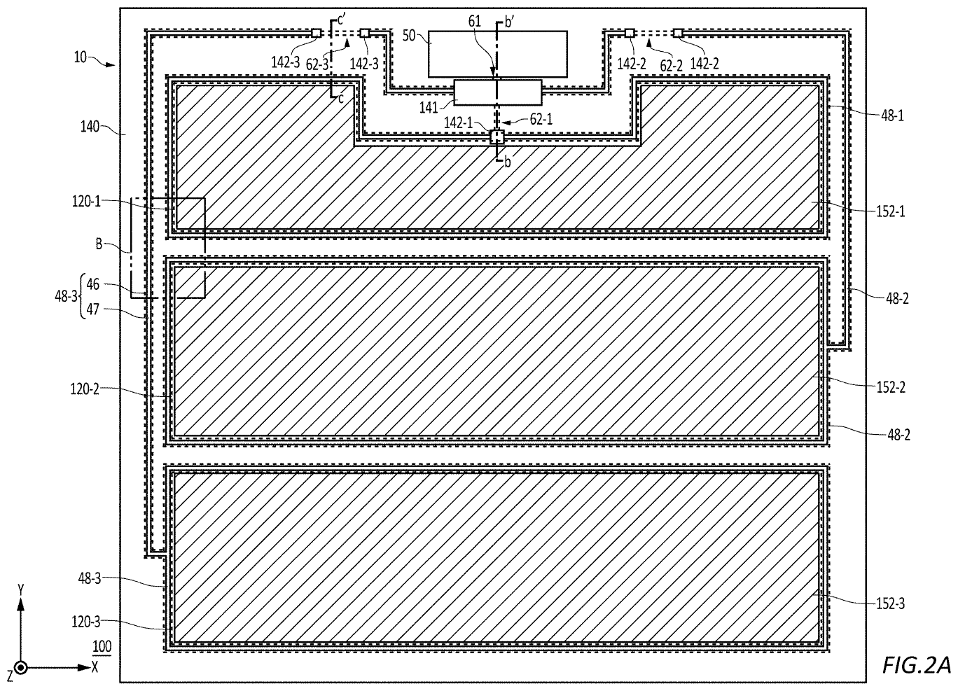

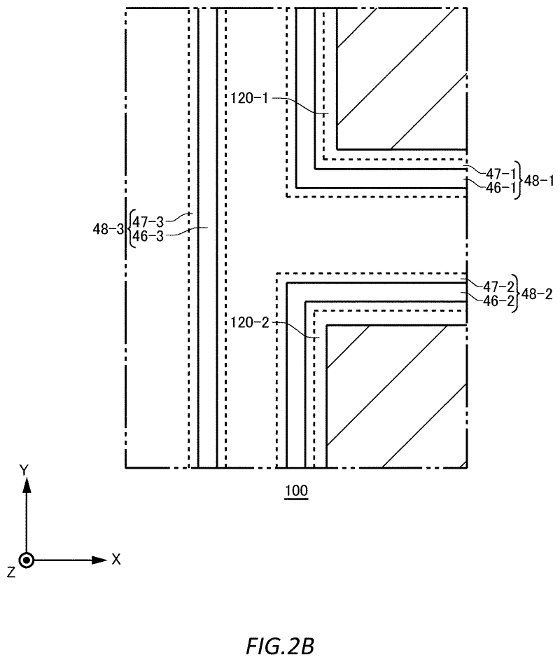

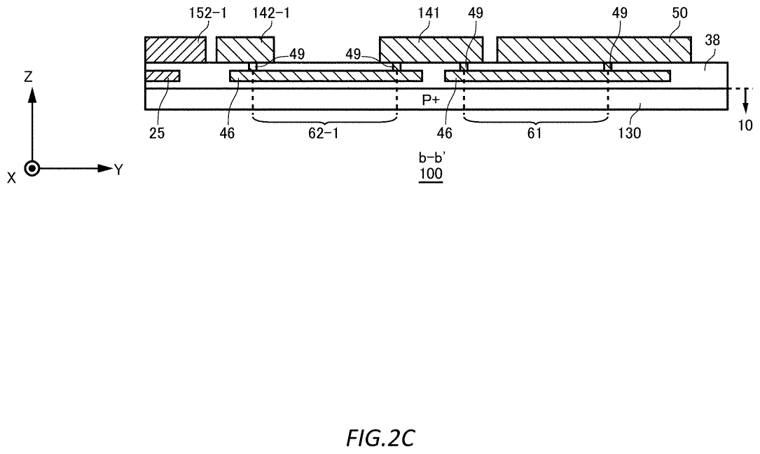

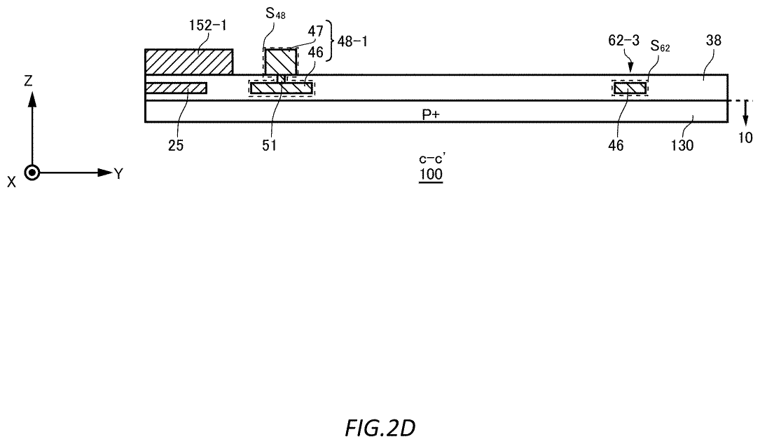

FIG. 2A illustrates an example of the upper surface of the semiconductor device 100. The semiconductor device 100 of the present example includes a gate wiring portion 48, a gate pad 50, a wiring resistance portion 62, a transistor region 120, an emitter electrode portion 152, a first resistance measurement pad 141, and a second resistance measurement pad 142. The semiconductor device 100 may include a built-in resistance portion 61. FIG. 2A illustrates an example embodiment which is provided with the plurality of gate wiring portions 48, the plurality of transistor regions 120, a plurality of emitter electrode portions 152, a plurality of wiring resistance portions 62, and a plurality of second resistance measurement pads 142 and includes the built-in resistance portion 61.

In the present specification, one gate wiring portion 48 means a wiring portion between the gate pad 50 and the gate conductive portion 44 of the gate trench portion 40 which is electrically connected between the gate pad 50 and the gate trench portion 40. One or more gate wiring portions 48 may extend from one gate pad 50. The gate wiring portion 48 may include a branch, and a branched part may be connected again. In the present example, each of the plurality of gate wiring portions 48 corresponds to any one of the plurality of transistor regions 120, and includes the gate metal layer 47 provided above the semiconductor substrate 10 and the gate runner 46 provided below the gate metal layer 47.

In FIG. 2A, the gate metal layer 47 is indicated by a solid line and the gate runner 46 is indicated by a dotted line. In the top view, a lateral width of the gate runner 46 may be wider than a lateral width of the gate metal layer 47. The gate runner 46 and the gate metal layer 47 may be at least partially overlapped in the top view.

The gate metal layer 47 is composed of a conductive metal material. In an example, the gate metal layer 47 is composed of tungsten (W). The gate metal layer 47 may be composed of a same material as the emitter electrode 52 and the collector electrode 24, or may be composed of a different material. Composing the gate metal layer 47 with a metal material can reduce a delay when a gate voltage is applied.

The gate runner 46 is composed of a conductive material. In an example, the gate runner 46 is composed of polysilicon. The gate runner 46 may be composed of a metal material. The gate runner 46 may be provided below the gate metal layer 47 and above the front surface 21 of the semiconductor substrate 10. The interlayer dielectric film 38 may be provided between the gate runner 46 and the gate metal layer 47.

The gate wiring portion 48 may be composed of only any one of the gate metal layer 47 or the gate runner 46. In an example, the gate wiring portion 48 is composed only of the gate runner 46. The gate wiring portion 48 may be composed of polysilicon.

The built-in resistance portion 61 includes one end electrically connected to the gate pad 50 and another end electrically connected to the plurality of gate wiring portions 48. The built-in resistance portion 61 may be provided between the gate pad 50 and the transistor region 120. The built-in resistance portion 61 of the present example is formed simultaneously with formation of the gate runner 46. That is, the built-in resistance portion 61 may be composed of polysilicon. This can reduce a number of at least one process since the built-in resistance portion 61 can be formed in a step of forming the gate wiring portion 48. The built-in resistance portion 61 may be composed of a resistance film other than polysilicon.

Providing the built-in resistance portion 61 may allow for adjustment of a relaxation time when the gate voltage is switched between on and off. This can attenuate a gate oscillation and a short-circuit oscillation between the semiconductor chips and suppress the oscillation when the plurality of semiconductor chips are connected in parallel.

Each of the wiring resistance portions 62 is provided between the first resistance measurement pad 141 and the transistor region 120 to correspond to each of the gate wiring portions 48. The wiring resistance portion 62 of the present example is a part of the gate wiring portion 48 without the gate metal layer 47. That is, the wiring resistance portion 62 may be composed of a single-layer structure made of polysilicon. This can reduce a number of at least one process since the wiring resistance portion 62 can be formed in a step of forming the gate wiring portion 48. The wiring resistance portion 62 may be a separate resistance portion which is not a part of the gate wiring portion 48. In an example, the wiring resistance portion 62 is composed of a resistance film other than polysilicon.

Providing the wiring resistance portions 62 may allow for the adjustment of a relaxation time when the gate voltage is switched between on and off. The wiring resistance portions 62, each of which corresponds to each of the gate wiring portions 48, can attenuate the gate oscillation and the short-circuit oscillation between the transistor regions 120 within the single semiconductor chip and suppress the oscillation when the plurality of transistor regions 120 and the plurality of gate wiring portions 48 are provided in parallel within the single semiconductor chip.

The first resistance measurement pad 141 is provided above the semiconductor substrate 10 and electrically connected to the gate pad 50 via the built-in resistance portion 61. A protective film (not shown) such as polyimide may not be provided above the first resistance measurement pad 141. The first resistance measurement pad 141 is composed of a conductive metal material. A material for the first resistance measurement pad 141 may be the same as or different from a material for the gate pad 50.

The first resistance measurement pad 141 is provided to partially overlap with the built-in resistance portion 61 in the top view, and the first resistance measurement pad 141 and the built-in resistance portion 61 are electrically connected via the contact hole 49. A detailed connection relationship between the first resistance measurement pad 141, the built-in resistance portion 61, and the gate pad 50 will be described below. The first resistance measurement pad 141 can measure a current and a voltage between the first resistance measurement pad 141 and the gate pad 50, and measure resistance of the built-in resistance portion 61.

The second resistance measurement pads 142 are provided above the semiconductor substrate 10 and electrically connected to each end of the wiring resistance portion 62. A protective film (not shown) such as polyimide may not be provided above the second resistance measurement pad 142. The second resistance measurement pad 142 is composed of a conductive metal material. A material for the second resistance measurement pad 142 may be the same as or different from a material for the first resistance measurement pad 141.

The second resistance measurement pads 142 are electrically connected via the wiring resistance portion 62 and the contact holes 49. A detailed connection relationship between the second resistance measurement pad 142 and the wiring resistance portion 62 will be described below. The second resistance measurement pad 142 can measure a current and a voltage between two second resistance measurement pads 142 and measure resistance of the wiring resistance portion 62.

The first resistance measurement pad 141 and the second resistance measurement pad 142 may be arranged so that they can measure resistance of the built-in resistance portion 61 and the wiring resistance portion 62 collectively. The second resistance measurement pad 142 may measure a current and a voltage between the first resistance measurement pad 141 and the second resistance measurement pad 142 and measure the resistance of the wiring resistance portion 62. As an example, when the wiring resistance portion 62 is connected to the first resistance measurement pad 141, resistance of the built-in resistance portion 61 can be measured by measuring a current and a voltage between the gate pad 50 and the first resistance measurement pad 141, and resistance of the wiring resistance portion 62 can be measured by measuring a current and a voltage between the first resistance measurement pad 141 and the second resistance measurement pad 142.

The transistor region 120 is a region through which the main current in the depth direction flows between the front surface 21 and the back surface 23 of the semiconductor substrate 10 when the semiconductor device 100 is operated. The transistor region 120 includes the transistor portion 70 and the diode portion 80. In the present specification, one transistor region 120 may be a region surrounded by one gate wiring portion 48.

The emitter electrode portion 152 is provided above the semiconductor substrate 10 and applies a potential which is different from the gate potential to the transistor region 120. The emitter electrode portion 152 of the present example is electrically insulated from the gate wiring portion 48. In the present specification, one emitter electrode portion 152 may be an emitter electrode composed of one continuous metal plate.

In the semiconductor device 100 illustrated in FIG. 2A, one gate pad 50 and the built-in resistance portion 61 electrically connected to the gate pad 50 are provided for the plurality of transistor regions 120. In the semiconductor device 100, one each of the transistor region 120, the gate pad 50, and the built-in resistance portion 61 electrically connected to the gate pad 50 may be provided. The built-in resistance portion 61 may not be provided in the semiconductor device 100. In the present example, one gate pad 50 and the built-in resistance portion 61 electrically connected to the gate pad 50 are provided for three transistor regions 120-1, 120-2, and 120-3. Providing the built-in resistance portion 61 can suppress the gate oscillation and the short-circuit oscillation between the semiconductor chips.

The example embodiment of FIG. 2A illustrates the semiconductor device 100 which includes the plurality of gate wiring portions 48 each of which corresponds to any one of the plurality of transistor regions 120. A number of the gate wiring portions 48 provided in the semiconductor device 100 may be the same as or different from a number of the transistor regions 120. In the present example, first gate wiring 48-1, second gate wiring 48-2, and third gate wiring 48-3 are provided to correspond to a first transistor region 120-1, a second transistor region 120-2, and a third transistor region 120-3, respectively.

The example embodiment of FIG. 2A illustrates the semiconductor device 100 which includes the plurality of wiring resistance portions 62 corresponding to each of the plurality of gate wiring portions 48. A number of the gate wiring portions 48 may be the same or different from a number of the wiring resistance portions 62 provided in the gate wiring portion 48. For each of the gate wiring portions 48, one wiring resistance portion 62 or two or more wiring resistance portions 62 may be provided.

The present example shows a first wiring resistance 62-1, a second wiring resistance 62-2, and a third wiring resistance 62-3 which correspond to the first gate wiring 48-1, the second gate wiring 48-2, and the third gate wiring 48-3, respectively. Providing the wiring resistance portion 62 for each of the gate wiring portions 48 can suppress an oscillation within the same chip, such as an oscillation between the first transistor region 120-1 and the second transistor region 120-2.

Each of the plurality of wiring resistance portions 62 is provided to connect to each of the plurality of transistor regions 120. The number of the wiring resistance portions 62 may be the same as or different from the number of the transistor regions 120. For each of the transistor regions 120, one wiring resistance portion 62 or two or more wiring resistance portions 62 may be provided.

In the present example, the first wiring resistance 62-1, the second wiring resistance 62-2, and the third wiring resistance 62-3 are provided to connect to the first transistor region 120-1, the second transistor region 120-2, and the third transistor region 120-3, respectively. Providing the wiring resistance portion 62 between the plurality of transistor regions 120 can suppress the oscillation within the same chip.

Each of the plurality of wiring resistance portions 62 is arranged closer to the gate pad 50 than to each of the plurality of transistor regions 120. For each gate wiring portion 48, a length of the gate wiring portion 48 from the first resistance measurement pad 141 to the wiring resistance portion 62 may be shorter than a length of the gate wiring portion 48 from the wiring resistance portion 62 to the transistor region 120. In this way, the first resistance measurement pad 141 and the plurality of second resistance measurement pads 142 may each be arranged near the gate pad 50, thereby improving detection accuracy for each resistance value.

A resistance value of each of the plurality of wiring resistance portions 62 may be greater than a resistance value of the built-in resistance portion 61. A resistance value which combines the plurality of wiring resistance portions 62 is greater than 0% and less than or equal to 100% of combined resistance of the built-in resistance portion 61 and the plurality of wiring resistance portions 62. In addition, combined resistance of the plurality of wiring resistance portions 62 may be 10% or more and 80% or less of the combined resistance of the built-in resistance portion 61 and the plurality of wiring resistance portions 62. When the resistance value of each of the plurality of wiring resistance portions 62 is greater than the resistance value of the built-in resistance portion 61, variation in resistance values of the wiring resistance portions 62 can be reduced and an operation characteristic of the semiconductor device 100 can be more uniform.

A resistance value of the combined resistance of the built-in resistance portion 61 and the plurality of wiring resistance portions 62 may be determined based on a rated output of the semiconductor device 100. In an example, the resistance value of the combined resistance of the built-in resistance portion 61 and the plurality of wiring resistance portions 62 is determined based on the rated output of the semiconductor device 100, and the resistance value of each of the plurality of wiring resistance portions 62 is determined based on the resistance value of the combined resistance. This makes it possible to suppress both an oscillation between the chips when the plurality of semiconductor chips are connected in parallel and the oscillation within the same chip while maintaining the required rated output of the semiconductor device 100.

The gate pad 50 is provided closer to an outer peripheral side of the semiconductor substrate 10 relative to the plurality of transistor regions 120 in the top view. Providing the gate pad 50 on the outer peripheral side of the semiconductor substrate 10 allows gate-wire wiring without interfering with main wiring.

The plurality of gate wiring portions 48 are spaced apart from each other in the top view. That is, in the present example, the first gate wiring 48-1, the second gate wiring 48-2, and the third gate wiring 48-3 are connected only in the first resistance measurement pad 141 and not connected in another location. This makes it possible to arrange the wiring resistance portion 62 between the plurality of transistor regions 120 and suppress the oscillation within the same chip.

The emitter electrode 52 may include the plurality of emitter electrode portions 152 spaced apart from each other. The emitter electrode 52 of the present example includes a first emitter electrode portion 152-1, a second emitter electrode portion 152-2, and a third emitter electrode portion 152-3.

Each of the plurality of emitter electrode portions 152 may correspond to each of the plurality of wiring resistance portions 62. The number of the wiring resistance portions 62 may be the same as or different from a number of the emitter electrode portions 152. For each of the emitter electrode portions 152, one wiring resistance portion 62 or two or more wiring resistance portions 62 may be provided. In the present example, the first emitter electrode portion 152-1, the second emitter electrode portion 152-2, and the third emitter electrode portion 152-3 correspond to the first wiring resistance 62-1, the second wiring resistance 62-2, and the third wiring resistance 62-3, respectively.

The plurality of transistor regions 120 may include two or more transistor regions with substantially same areas. The transistor regions of the present example include the first transistor region 120-1 and the second transistor region 120-2 with substantially same areas. In the present specification, the phrase “transistor regions 120 with substantially same areas” can mean that a difference in areas between two transistor regions 120 is within 10%. When areas of the plurality of transistor regions 120 are substantially the same, a difference in active areas among the transistor regions 120 becomes smaller, current crowding when the semiconductor device 100 is turned off is reduced, and latch-up resistance is improved.

A length of each of the plurality of gate wiring portions 48 may be different for each gate wiring portion 48 or may all be the same. The length of the gate wiring portion 48 may be adjusted appropriately depending on an arrangement of the gate pad 50 and the transistor regions 120 in the semiconductor device 100. In the present example, the plurality of gate wiring portions include the first gate wiring 48-1 connected to the first transistor region 120-1, and the second gate wiring 48-2 which is connected to the second transistor region 120-2 and longer than the first gate wiring 48-1.

A length of each of the plurality of gate wiring portions 48 may be adjusted appropriately as long as a gate signal delay does not occur among the plurality of transistor regions 120 to which each gate wiring portion 48 is connected. The length of each of the plurality of gate wiring portions 48 may be adjusted so that a gate resistance value is less than or equal to a predetermined value in any region of the plurality of transistor regions 120. In each transistor region 120, a resistance value across the gate trench portion 40 which connects to the gate wiring portion 48 may be 6 kΩ or less for one gate trench portion 40 in any region.

The resistance value of each of the plurality of wiring resistance portions 62 may be different for each wiring resistance portion 62 or may all be the same. The resistance value of each wiring resistance portion 62 among the plurality of wiring resistance portions 62 may be 3Ω or more and may be 30Ω or less. The resistance value of each of the plurality of wiring resistance portions 62 may be changed depending on a capacitance of the transistor region 120 to which each wiring resistance portion 62 is connected, depending on a magnitude of a mutual inductance that the gate wiring portion 48 in which each wiring resistance portion 62 is arranged receives from a surrounding gate wiring portion 48, and depending on resonant strength of an LC resonant circuit formed within the same chip.

The resistance value of each wiring resistance portion 62 among the plurality of wiring resistance portions 62 may be changed depending on an area of the transistor region 120 to which each wiring resistance portion 62 is connected. In the present example, wiring resistance portions 62-1 and 62-2 connected to the first transistor region 120-1 and the second transistor region 120-2 with substantially same areas may have substantially the same resistance values. In the present specification, the phrase “wiring resistance portions 62 have substantially the same resistance values” can mean that a difference in resistance value between two wiring resistance portions 62 is within 10%.

The resistance value of each of the plurality of wiring resistance portions 62 may be changed depending on the length of the gate wiring portion 48 for which each wiring resistance portion 62 is provided. In the present example, a resistance value of the first wiring resistance 62-1 connected to the first gate wiring 48-1 is greater than a resistance value of the second wiring resistance 62-2 connected to the second gate wiring 48-2. In general, the larger the length of the gate wiring portion 48, the larger a parasitic capacitance in that gate wiring portion 48. Thus, the oscillation can be suppressed even when a resistance value of the wiring resistance portion 62 in that gate wiring portion 48 is smaller than a resistance value of the wiring resistance portion 62 in another gate wiring portion 48.

The resistance value of each of the plurality of wiring resistance portions 62 may be changed depending on an error in a CR time constant which is a product of a capacitance C of each transistor region 120 of the plurality of transistor regions 120 and a resistance value R of each wiring resistance portion 62 corresponding to each transistor region 120. In the present example, the error in values of the CR time constant which is the product of the capacitance C of the transistor region 120 and the resistance value R of the wiring resistance portion 62 corresponding to that transistor region 120 is 10% or less among respective transistor regions 120 of the plurality of transistor regions 120. The error may be 20% or less. By keeping the error in the CR time constant at 20% or less, non-uniformity of a current during a switching operation of the semiconductor device 100 can be eliminated.

FIG. 2B illustrates an example of an enlarged view of the upper surface of the semiconductor device 100. FIG. 2B is an enlarged view of a region B surrounded with a double dotted line in FIG. 2A. The first gate wiring 48-1 may include a first gate metal layer 47-1 and a first gate runner 46-1, the second gate wiring 48-2 may include a second gate metal layer 47-2 and a second gate runner 46-2, and the third gate wiring 48-3 may include a third gate metal layer 47-3 and a third gate runner 46-3.

The plurality of gate wiring portions 48 may include a gate wiring portion 48 which is provided between two adjacent transistor regions 120 among the plurality of transistor regions 120 and connected to one of the two adjacent transistor regions 120, and a gate wiring portion 48 which is provided between the two adjacent transistor regions 120 and connected to another of the two adjacent transistor regions 120. In the present example, the first gate wiring 48-1 connected to the first transistor region 120-1 and the second gate wiring 48-2 connected to the second transistor region 120-2 are provided between the two adjacent transistor regions 120 of the first transistor region 120-1 and the second transistor region 120-2.

Three or more gate wiring portions 48 may be provided between the two adjacent transistor regions 120. Although the third gate wiring 48-3 is not provided between the first transistor region 120-1 and the second transistor region 120-2 in the present example, the third gate wiring 48-3 may be provided between the first transistor region 120-1 and the second transistor region 120-2.

Each of the plurality of transistor regions 120 is provided with the gate trench portion 40. The gate trench portion 40 is electrically connected to the gate wiring portion 48 which corresponds to each of the transistor regions 120. The gate trench portion 40 extends in a predetermined extension direction, i.e., the Y-axis direction in the present example.

The gate trench portion 40 may be connected only to one gate wiring portion 48. As an example, the gate trench portion 40 included in the first transistor region 120-1 is connected only to the first gate wiring 48-1 among the plurality of gate wiring portions 48. The gate trench portion 40 included in the first transistor region 120-1 and the gate trench portion 40 included in the second transistor region 120-2 may be separated from each other by the first gate wiring 48-1 and the second gate wiring 48-2.

At least some gate trench portions 40 among a plurality of gate trench portions 40 included in the transistor regions 120 may span adjacent transistor regions 120. At least some gate trench portions 40 among the plurality of gate trench portions 40 may connect to the plurality of gate wiring portions 48. That is, in the example illustrated in FIG. 2B, at least some gate trench portions 40 among the plurality of gate trench portions 40 may extend transversely under the first gate wiring 48-1 and/or the second gate wiring 48-2 in a trench extension direction, i.e., the Y-axis direction in the present example, and span both the first transistor region 120-1 and the second transistor region 120-2.

FIG. 2C illustrates an example of a cross section b-b′ of the semiconductor device 100. The cross section b-b′ is a Y-Z cross section through the gate pad 50, the first resistance measurement pad 141, the second resistance measurement pad 142-1, the built-in resistance portion 61, and the first wiring resistance 62-1 in the semiconductor device 100.

The built-in resistance portion 61 is provided between the gate pad 50 and the first resistance measurement pad 141 above the semiconductor substrate 10. The built-in resistance portion 61 is provided inside the interlayer dielectric film 38. The built-in resistance portion 61 may be composed of polysilicon. The built-in resistance portion 61 may be a part of the gate runner 46.

The built-in resistance portion 61 is electrically connected to the gate pad 50 and the first resistance measurement pad 141 via two contact holes 49. Providing a resistance between the gate pad 50 and the plurality of gate wiring portions 48 can suppress the oscillation between the chips when the plurality of semiconductor chips are connected in parallel.

The first wiring resistance 62-1 is provided between the first resistance measurement pad 141 and the second resistance measurement pad 142-1 above the semiconductor substrate 10. The wiring resistance portion 62 may be provided between two second resistance measurement pads 142. The wiring resistance portion 62 may be provided at a same depth as, or at a different depth from, that of the built-in resistance portion 61 in the depth direction of the semiconductor substrate 10. The wiring resistance portion 62 is provided inside the interlayer dielectric film 38. The wiring resistance portion 62 may be composed of polysilicon. The wiring resistance portion 62 may be a part of the gate runner 46.

The first wiring resistance 62-1 is electrically connected to the first resistance measurement pad 141 and the second resistance measurement pad 142-1 via two contact holes 49. The wiring resistance portion 62 may be electrically connected to two second resistance measurement pads 142 via two contact holes 49. The wiring resistance portion 62 may be provided as a part of the gate wiring portion 48. Providing the wiring resistance portion 62 in the gate wiring portion 48 can suppress the oscillation inside the semiconductor chip.

The first emitter electrode portion 152-1 is spaced apart from the second resistance measurement pad 142-1. The emitter electrode 52 may be spaced apart from each of the plurality of gate wiring portions 48. The first emitter electrode portion 152-1 may be electrically connected to the connection portion 25 inside the interlayer dielectric film 38.

FIG. 2D illustrates an example of a cross section c-c′ of the semiconductor device 100. The cross section c-c′ is a Y-Z cross section through the first gate wiring 48-1 and the third wiring resistance 62-3 in the semiconductor device 100.

The first gate wiring 48-1 includes the gate metal layer 47 provided above the semiconductor substrate 10 and the gate runner 46 provided below the gate metal layer 47. The gate runner 46 may be provided inside the interlayer dielectric film 38. The first gate wiring 48-1 may be composed of only one of the gate metal layer 47 or the gate runner 46.

The semiconductor device 100 of the present example may include a contact portion 51 which is provided between the gate metal layer 47 and the gate runner 46 and electrically connects the gate metal layer 47 and the gate runner 46. This can improve a degree of flexibility in wiring of the gate wiring portion 48.

A cross-sectional area of the wiring resistance portion 62 perpendicular to its extension direction may be smaller than a cross-sectional area of the gate wiring portion 48 perpendicular to its extension direction. In the present example, in the Y-Z cross section illustrated in FIG. 2D, a cross-sectional area S₆₂ of the third wiring resistance 62-3 is smaller than a cross-sectional area S₄₈ of the first gate wiring 48-1. This can make the resistance value of the wiring resistance portion 62 greater than a resistance value of the gate wiring portion 48 to suppress the oscillation within a single semiconductor chip.

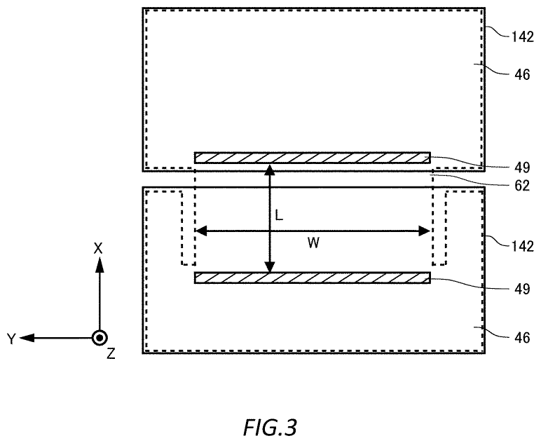

FIG. 3 is an enlarged view of a resistance measurement pad of the present example. Although FIG. 3 illustrates an example of an upper surface of the second resistance measurement pad 142, an upper surface of the first resistance measurement pad 141 may be of the same aspect. As illustrated in FIG. 3, two second resistance measurement pads 142 are connected to the wiring resistance portion 62 provided below the second resistance measurement pads 142 via contact holes 49.

The wiring resistance portion 62 may be a part of the gate runner 46. In the present example, the wiring resistance portion 62 is a region with a width W and a length L provided between two contact holes 49. The resistance value of the wiring resistance portion 62 can be adjusted by changing the width W and the length L of the wiring resistance portion 62.

The width W of the wiring resistance portion 62 may be smaller than a width of the gate runner 46 in the gate wiring portion 48 in a direction perpendicular to the extension direction. The width W of the wiring resistance portion 62 may be the same as a width of the gate metal layer 47 in the gate wiring portion 48 in a direction perpendicular to the extension direction, or may be smaller than the width of the gate metal layer 47. The width W of the wiring resistance portion 62 may be smaller than a width of the second resistance measurement pad 142 in a direction perpendicular to the extension direction of the gate wiring portion 48. The width W of the wiring resistance portion 62 may be 30 μm or more and may be 1400 μm or less.

The length L of the wiring resistance portion 62 may be smaller than the width W of the wiring resistance portion 62. The length L of the wiring resistance portion 62 may be smaller than a width of the second resistance measurement pad 142 in the extension direction of the gate wiring portion 48. The length L of the wiring resistance portion 62 may be 20 μm or more and 800 μm or less.

An ammeter and a voltmeter not shown are provided between two second resistance measurement pads 142. This makes it possible to calculate a resistance value of the wiring resistance portion 62 between the contact holes 49.

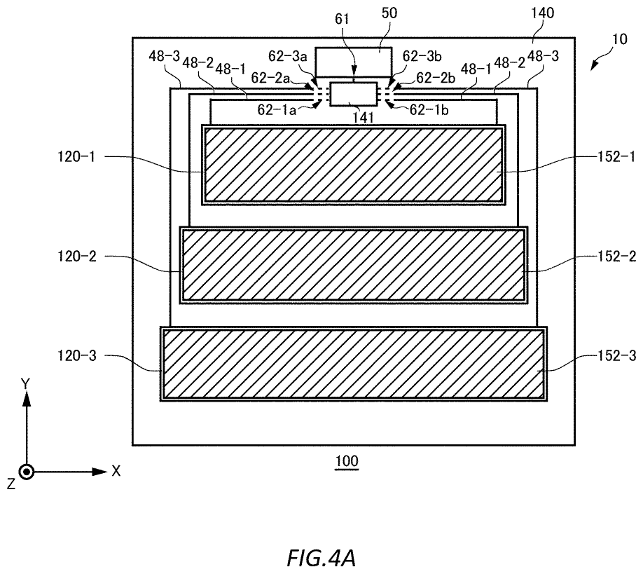

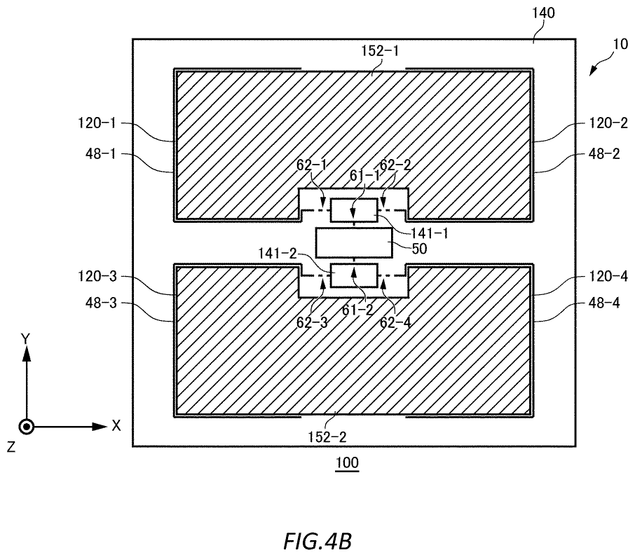

FIG. 4A illustrates a modification example of the upper surface of the semiconductor device 100. The modification example in FIG. 4A will be described with respect to a difference from FIG. 2A. For simplicity, the gate wiring portion 48 is indicated by a solid line and the wiring resistance portion 62 provided in the gate wiring portion 48 is indicated by a dotted line. Note that a position of each wiring in the figure merely shows an approximate position in order to avoid confusion with another wiring. In addition, an illustration of the second resistance measurement pad 142 is omitted.

In the modification example in FIG. 4A, two or more wiring resistance portions 62 among the plurality of wiring resistance portions 62 are connected to one transistor region 120 among the plurality of transistor regions 120. As an example, the first wiring resistance 62-1 and the second wiring resistance 62-2 are connected to the first transistor region 120-1.

In the present example, two first wiring resistances 62-1a and 62-1b are connected to the first transistor region 120-1, two second wiring resistances 62-2a and 62-2b are connected to the second transistor region 120-2, and two third wiring resistance 62-3a and 62-3b are connected to the third transistor region 120-3. This makes it possible to increase the resistance value of the gate wiring portion 48 provided for each transistor region 120 and suppress the oscillation within the single semiconductor chip.

In the modification example in FIG. 4A, one emitter electrode portion 152 among the plurality of emitter electrode portions 152 corresponds to two or more wiring resistance portions 62 among the plurality of wiring resistance portions 62. In the present example, the first emitter electrode portion 152-1 corresponds to the first wiring resistances 62-1a and 62-1b, the second emitter electrode portion 152-2 corresponds to the second wiring resistances 62-2a and 62-2b, and the third emitter electrode portion 152-3 corresponds to the third wiring resistances 62-3a and 62-3b.

The plurality of transistor regions 120 may include two or more transistor regions with different areas. The transistor regions of the present example include the first transistor region 120-1, the second transistor region 120-2 with a larger area than the first transistor region 120-1, and the third transistor region 120-3 with a larger area than the second transistor region 120-2.

The resistance value of each wiring resistance portion 62 among the plurality of wiring resistance portions may be changed depending on an area of the transistor region 120 to which each wiring resistance portion 62 is connected. In the present example, resistance values of the first wiring resistances 62-1a and 62-1b connected to the first transistor region 120-1 are greater than resistance values of the second wiring resistances 62-2a and 62-2b connected to the second transistor region 120-2, and resistance values of the second wiring resistances 62-2a and 62-2b connected to the second transistor region 120-2 are greater than resistance values of the third wiring resistances 62-3a and 62-3b connected to the third transistor region 120-3.

In general, the larger the area of the transistor region 120, the larger a parasitic capacitance in that transistor region 120. Thus, the oscillation can be suppressed even when a resistance value of the wiring resistance portion 62 for that transistor region 120 is smaller than a resistance value of the wiring resistance portion 62 for another transistor region 120. When an area of the transistor region 120 is denoted as S and a resistance value of the wiring resistance portion 62 connected to that transistor region 120 is denoted as R, a resistance value R of the wiring resistance portion 62 may be adjusted such that a value of S*R assumes a predetermined value.

FIG. 4B illustrates a modification example of the upper surface of the semiconductor device 100. The modification example in FIG. 4B will be described with respect to a difference from FIG. 2A and FIG. 4A.

The gate pad 50 may be provided between the plurality of transistor regions 120 in the top view. In the present example, the gate pad 50 is provided near a center of the semiconductor device 100 between the plurality of transistor regions 120. This can improve symmetry of a configuration of the semiconductor device 100 and make gate-signal transmission in the semiconductor device 100 more uniform.

The built-in resistance portion 61 may include a first built-in resistance 61-1 and a second built-in resistance 61-2 different from the first built-in resistance 61-1. The built-in resistance portion 61 may include three or more built-in resistances. In the present example, the built-in resistance portion 61 includes the first built-in resistance 61-1 connected to the gate pad 50 and the second built-in resistance 61-2 which is connected to the gate pad 50 and different from the first built-in resistance 61-1. A resistance value of each of the first built-in resistance 61-1 and the second built-in resistance 61-2 may be the same or different.

The plurality of wiring resistance portions 62 may include one or more first wiring resistances 62-1 connected to the first built-in resistance 61-1 and one or more second wiring resistances 62-2 which is connected to the second built-in resistance 61-2 and different from the first wiring resistances 62-1. In the present example, the plurality of wiring resistance portions include the first wiring resistance 62-1 and the second wiring resistance 62-2 connected to the first built-in resistance 61-1 and the third wiring resistance 62-3 and a fourth wiring resistance 62-4 connected to the second built-in resistance 61-2. Three or more wiring resistances may be connected to one built-in resistance. When a plurality of built-in resistance portions 61 and the plurality of wiring resistance portions 62 are provided, a resistance value to suppress the oscillation between the semiconductor chips and a resistance value to suppress the oscillation within the semiconductor chip can be adjusted separately.

The emitter electrode portion 152 may correspond to a plurality of different transistor regions 120. The emitter electrode portion 152 may correspond to the plurality of different transistor regions 120 connected to one built-in resistance. In the present example, the first emitter electrode portion 152-1 corresponds to the first transistor region 120-1 and the second transistor region 120-2 which are connected to the first built-in resistance 61-1 and the second emitter electrode portion 152-2 corresponds to the third transistor region 120-3 and a fourth transistor region 120-4 which are connected to the second built-in resistance 61-2.

In the present example, the emitter electrode portion 152 does not overlap with the gate wiring portion 48 in the top view. The emitter electrode portion 152 may overlap with the gate wiring portion 48 in the top view. In this case, the overlapping portion is not provided with the gate metal layer 47. That is, the emitter electrode portion 152 and the gate wiring portion 48 are not electrically connected. The portion without the gate metal layer 47 may be provided with the gate runner 46.

There may be provided a plurality of first resistance measurement pads 141. The plurality of first resistance measurement pads 141 may correspond to a plurality of built-in resistances included in the built-in resistance portion 61. One first resistance measurement pad 141 may measure resistance values of the plurality of built-in resistances. In the present example, the first resistance measurement pad 141-1 corresponds to the first built-in resistance 61-1 and the first resistance measurement pad 141-2 corresponds to the second built-in resistance 61-2.

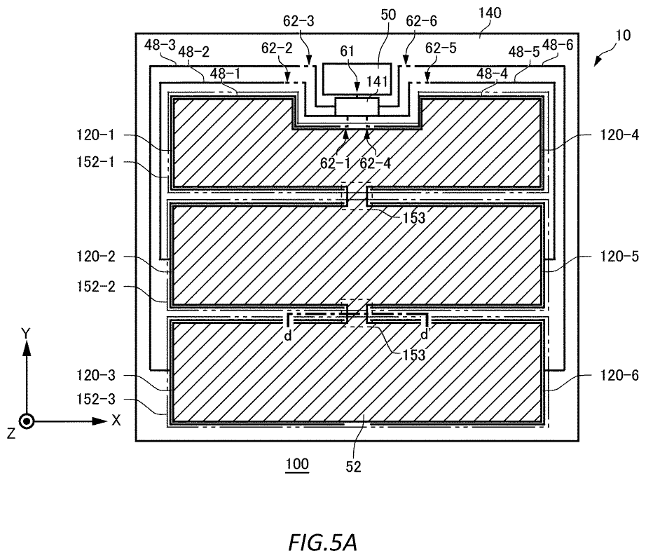

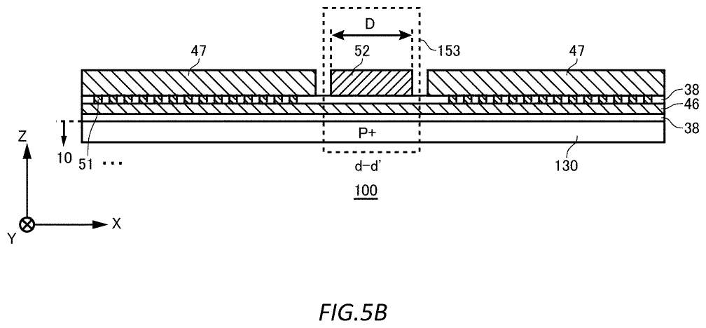

FIG. 5A illustrates a modification example of the upper surface of the semiconductor device 100. The modification example in FIG. 5A will be described with respect to a difference from FIG. 2A, FIG. 4A, and FIG. 4B.

The plurality of wiring resistance portions 62 may be provided with a common emitter electrode 52 above the semiconductor substrate 10. Above the semiconductor substrate 10, the common emitter electrode 52 may be provided for the plurality of gate wiring portions 48 and the plurality of transistor regions 120. In the present example, one common emitter electrode 52 is provided for the plurality of wiring resistance portions 62-1, 62-2, 62-3, 62-4, 62-5, and 62-6.

The example embodiment of FIG. 5A is different from the example embodiment of FIG. 2A in that respective emitter electrode portions 152 indicated by a double dotted line are connected by connection regions 153 with each other. In the present example, the first emitter electrode portion 152-1 corresponding to the first transistor region 120-1 and the fourth transistor region 120-4, the second emitter electrode portion 152-2 corresponding to the second transistor region 120-2 and a fifth transistor region 120-5, and the third emitter electrode portion 152-3 corresponding to the third transistor region 120-3 and a sixth transistor region 120-6 are connected each other by the connection regions 153. Connecting the respective emitter electrode portions 152 by the connection regions 153 to form one emitter electrode 52 can improve operational stability of the semiconductor device 100.

FIG. 5B illustrates an example of a cross section d-d′ of the semiconductor device 100 in FIG. 5A. The cross section d-d′ is an XZ cross section through the gate wiring portion 48 and the emitter electrode 52.

The gate wiring portion 48 is spaced apart from the emitter electrode 52. The gate runner 46 of the gate wiring portion 48 is connected to the gate metal layer 47 via the contact portion 51. The contact portion 51 is not provided under the emitter electrode 52. That is, the gate runner 46 is not electrically connected to the emitter electrode 52. In this way, the gate wiring portion 48 and the emitter electrode 52 can be electrically insulated.

The gate runner 46 may not be provided under the emitter electrode 52. In the present example, the gate runner 46 is provided under the emitter electrode 52. In this way, even when the gate metal layer 47 is separated by the emitter electrode 52 above the semiconductor substrate 10, the gate runner 46 allows the gate wiring portion 48 to remain continuous.

The emitter electrode 52 in the connection region 153 has a predetermined width D in a direction perpendicular to a connection direction of the emitter electrode portions 152. The width D may be greater than a width between the emitter electrode 52 and the gate metal layer 47. The width D may be 0 μm or more and may be less than or equal to a width of the emitter electrode portion 152. The width D may be 1000 μm or less.

While the present invention has been described above by way of the embodiments, the technical scope of the present invention is not limited to the scope described in the above-described embodiments. It is apparent to persons skilled in the art that various alterations or improvements can be made to the above-described embodiments. It is also apparent from the description of the claims that the embodiments to which such alterations or improvements are made can fall within the technical scope of the present invention.

Each process of the operations, procedures, steps, stages, and the like performed by a device, system, program, and method shown in the claims, the specification, and the drawings can be performed in any order as long as the order is not indicated by “prior to,” “before,” and the like and as long as the output from a previous process is not used in a later process. Even if the operational flow is described using phrases such as “first” or “next” for convenience in the claims, the specification, and the drawings, it does not necessarily mean that the process must be performed in this order.

### Item 1

A semiconductor device comprising:
a plurality of transistor regions;
a gate trench portion provided in each of the plurality of transistor regions;
a gate pad provided above a semiconductor substrate;
a plurality of gate wiring portions, each of which is electrically connected between the gate pad and the gate trench portion and corresponds to any one of the plurality of transistor regions; and
a plurality of wiring resistance portions, each of which corresponds to each of the plurality of gate wiring portions.

### Item 2

The semiconductor device according to item 1, comprising a built-in resistance portion one end of which is electrically connected to the gate pad and another end of which is electrically connected to the plurality of gate wiring portions.

### Item 3

The semiconductor device according to item 1, wherein each of the plurality of gate wiring portions comprises a gate metal layer provided above the semiconductor substrate and a gate runner provided below the gate metal layer.

### Item 4

The semiconductor device according to item 3, comprising a contact portion which I provided between the gate metal layer and the gate runner and connects the gate metal layer and the gate runner.

### Item 5

The semiconductor device according to item 1 wherein the gate pad is provided closer to an outer peripheral side of the semiconductor substrate relative to the plurality of transistor regions in a top view.

### Item 6

The semiconductor device according to item 1, wherein each of the plurality of wiring resistance portions is connected to each of the plurality of transistor regions.

### Item 7

The semiconductor device according to item 1, wherein two or more wiring resistance portions among the plurality of wiring resistance portions are connected to one transistor region among the plurality of transistor regions.

### Item 8

The semiconductor device according to item 2, wherein the gate pad is provided between the plurality of transistor regions in a top view.

### Item 9

The semiconductor device according to item 8, wherein
the built-in resistance portion comprises a first built-in resistance and a second built-in resistance which is different from the first built-in resistance, and
the plurality of wiring resistance portions comprise one or more first wiring resistances which are connected to the first built-in resistance and one or more second wiring resistances which are connected to the second built-in resistance and different from the one or more first wiring resistances.

### Item 10

The semiconductor device according to item 1, wherein the plurality of gate wiring portions are spaced apart from each other in a top view.

### Item 11

The semiconductor device according to item 1, wherein
each of the plurality of wiring resistance portions is provided in any one of the plurality of gate wiring portions, and
a cross-sectional area of the wiring resistance portion perpendicular to its extension direction is smaller than a cross-sectional area of the gate wiring portion perpendicular to its extension direction.

### Item 12

The semiconductor device according to item 1, wherein each of the plurality of wiring resistance portions is arranged closer to the gate pad than to each of the plurality of transistor regions.

### Item 13

The semiconductor device according to item 1, wherein the plurality of gate wiring portions is composed of polysilicon.

### Item 14

The semiconductor device according to item 2, wherein the built-in resistance portion is composed of polysilicon.

### Item 15

The semiconductor device according to item 1, wherein each of the plurality of wiring resistance portions is composed of a single-layer structure made of polysilicon.

### Item 16

The semiconductor device according to item 2, comprising a first resistance measurement pad to measure resistance of the built-in resistance portion.

### Item 17

The semiconductor device according to item 1, comprising a second resistance measurement pad to measure resistance of each of the plurality of wiring resistance portions.

### Item 18

The semiconductor device according to item 1, comprising:
an emitter electrode provided above the semiconductor substrate, wherein
the emitter electrode comprises a plurality of emitter electrode portions spaced apart from each other, and
each of the plurality of emitter electrode portions corresponds to each of the plurality of wiring resistance portions.

### Item 19

The semiconductor device according to item 1, comprising:
an emitter electrode provided above the semiconductor substrate, wherein the emitter electrode comprises a plurality of emitter electrode portions spaced apart from each other, and
one emitter electrode portion among the plurality of emitter electrode portions corresponds to two or more wiring resistance portions among the plurality of wiring resistance portions.

### Item 20

The semiconductor device according to item 1, comprising one common emitter electrode provided for the plurality of wiring resistance portions above the semiconductor substrate.

### Item 21

The semiconductor device according to item 2, wherein a resistance value which combines the plurality of wiring resistance portions is 10% or more and 80% or less of combined resistance of the built-in resistance portion and the plurality of wiring resistance portions.

### Item 22

The semiconductor device according to any one of items 1 to 21, wherein
the plurality of gate wiring portions comprise first gate wiring and second gate wiring which is longer than the first gate wiring, and
a resistance value of a wiring resistance portion of the plurality of wiring resistance portions which is connected to the first gate wiring is greater than a resistance value of a wiring resistance portion of the plurality of wiring resistance portions which is connected to the second gate wiring.

### Item 23

The semiconductor device according to any one of items 1 to 21, wherein
the plurality of transistor regions comprise a first transistor region and a second transistor region with substantially a same area as the first transistor region, and
a resistance value of a wiring resistance portion of the plurality of wiring resistance portions which is provided in a gate wiring portion of the plurality of gate wiring portions which is connected to a gate conductive portion in the first transistor region is substantially the same as a resistance value of a wiring resistance portion of the plurality of wiring resistance portions which is provided in a gate wiring portion of the plurality of gate wiring portions which is connected to a gate conductive portion in the second transistor region.

### Item 24

The semiconductor device according to any one of items 1 to 21, wherein
the plurality of transistor regions comprise a first transistor region and a second transistor region with a larger area than the first transistor region, and
a resistance value of a wiring resistance portion of the plurality of wiring resistance portions which is provided in a gate wiring portion of the plurality of gate wiring portions which is connected to a gate conductive portion in the first transistor region is greater than a resistance value of a wiring resistance portion of the plurality of wiring resistance portions which is provided in a gate wiring portion of the plurality of gate wiring portions which is connected to a gate conductive portion in the second transistor region.

### Item 25

The semiconductor device according to any one of items 1 to 21, wherein a resistance value of each wiring resistance portion among the plurality of wiring resistance portions is 3Ω or more and 30Ω or less.

### Item 26

The semiconductor device according to any one of items 1 to 21, wherein a resistance value of the gate trench portion is 6 kΩ or less in any of the plurality of transistor regions.

### Item 27

The semiconductor device according to any one of items 1 to 21, wherein an error in values of a CR time constant which is a product of a capacitance of a transistor region of the plurality of transistor regions and a resistance value of a wiring resistance portion of the plurality of wiring resistance portions which corresponds to the transistor region is within 20% in each transistor region of the plurality of transistor regions.

### Item 28

The semiconductor device according to any one of items 1 to 21, wherein the plurality of gate wiring portions comprise a gate wiring portion which is provided between two adjacent transistor regions among the plurality of transistor regions and connected to one of the two adjacent transistor regions, and a gate wiring portion which is provided between the two adjacent transistor regions and connected to another of the two adjacent transistor regions.

### EXPLANATION OF REFERENCES

10: semiconductor substrate; 12: emitter region; 14: base region; 15: contact region; 16: accumulation region; 18: drift region; 20: buffer region; 21: front surface; 22: collector region; 23: back surface; 24: collector electrode; 25: connection portion; 30: dummy trench portion; 31: extension part; 32: dummy dielectric film; 33: connection part; 34: dummy conductive portion; 38: interlayer dielectric film; 40: gate trench portion; 41: extension part; 42: gate dielectric film; 43: connection part; 44: gate conductive portion; 46: gate runner; 47: gate metal layer; 48: gate wiring portion; 49: contact hole; 50: gate pad; 51: contact portion; 52: emitter electrode; 54: contact hole; 55: contact hole; 56: contact hole; 61: built-in resistance portion; 62: wiring resistance portion; 70: transistor portion; 80: diode portion; 82: cathode region; 100: semiconductor device; 102: end side; 120: transistor region; 130: well region; 140: edge termination structure portion; 141: first resistance measurement pad; 142: second resistance measurement pad; 152: emitter electrode portion; 153: connection region.

What is claimed is:

1. A semiconductor device comprising:
a plurality of transistor regions;
a gate portion provided in each of the plurality of transistor regions;
a gate pad provided above a semiconductor substrate;
a plurality of gate wiring portions, each of which is electrically connected between the gate pad and the gate portion and corresponds to any one of the plurality of transistor regions; and
a plurality of wiring resistance portions, each of which corresponds to each of the plurality of gate wiring portions.

2. The semiconductor device according to claim 1, comprising a built-in resistance portion one end of which is electrically connected to the gate pad and another end of which is electrically connected to the plurality of gate wiring portions.

3. The semiconductor device according to claim 1, wherein each of the plurality of gate wiring portions comprises a gate metal layer provided above the semiconductor substrate and a gate runner provided below the gate metal layer.

4. The semiconductor device according to claim 3, comprising a contact portion which is provided between the gate metal layer and the gate runner and connects the gate metal layer and the gate runner.

5. The semiconductor device according to claim 1, wherein the gate pad is provided closer to an outer peripheral side of the semiconductor substrate relative to the plurality of transistor regions in a top view.

6. The semiconductor device according to claim 1, wherein each of the plurality of wiring resistance portions is connected to each of the plurality of transistor regions.

7. The semiconductor device according to claim 1, wherein two or more wiring resistance portions among the plurality of wiring resistance portions are connected to one transistor region among the plurality of transistor regions.

8. The semiconductor device according to claim 1, wherein the gate pad is provided between the plurality of transistor regions in a top view.

9. The semiconductor device according to claim 2, wherein
the built-in resistance portion comprises a first built-in resistance and a second built-in resistance which is different from the first built-in resistance, and
the plurality of wiring resistance portions comprise one or more first wiring resistances which are connected to the first built-in resistance and one or more second wiring resistances which are connected to the second built-in resistance and different from the one or more first wiring resistances.

10. The semiconductor device according to claim 1, wherein the plurality of gate wiring portions are spaced apart from each other in a top view.

11. The semiconductor device according to claim 1, wherein
each of the plurality of wiring resistance portions is provided in any one of the plurality of gate wiring portions, and
a cross-sectional area of the wiring resistance portion perpendicular to its extension direction is smaller than a cross-sectional area of the gate wiring portion perpendicular to its extension direction.

12. The semiconductor device according to claim 1, wherein each of the plurality of wiring resistance portions is arranged closer to the gate pad than to each of the plurality of transistor regions.

13. The semiconductor device according to claim 1, comprising:
an emitter electrode provided above the semiconductor substrate, wherein
the emitter electrode comprises a plurality of emitter electrode portions spaced apart from each other, and
each of the plurality of emitter electrode portions corresponds to each of the plurality of wiring resistance portions.

14. The semiconductor device according to claim 1, comprising:
an emitter electrode provided above the semiconductor substrate, wherein
the emitter electrode comprises a plurality of emitter electrode portions spaced apart from each other, and
one emitter electrode portion among the plurality of emitter electrode portions corresponds to two or more wiring resistance portions among the plurality of wiring resistance portions.

15. The semiconductor device according to claim 1, comprising one common emitter electrode provided for the plurality of wiring resistance portions above the semiconductor substrate.

16. The semiconductor device according to claim 1, wherein
the plurality of gate wiring portions comprise first gate wiring and second gate wiring which is longer than the first gate wiring, and
a resistance value of a wiring resistance portion of the plurality of wiring resistance portions which is connected to the first gate wiring is greater than a resistance value of a wiring resistance portion of the plurality of wiring resistance portions which is connected to the second gate wiring.

17. The semiconductor device according to claim 1, wherein
the plurality of transistor regions comprise a first transistor region and a second transistor region with substantially a same area as the first transistor region, and
a resistance value of a wiring resistance portion of the plurality of wiring resistance portions which is provided in a gate wiring portion of the plurality of gate wiring portions which is connected to a gate conductive portion in the first transistor region is substantially the same as a resistance value of a wiring resistance portion of the plurality of wiring resistance portions which is provided in a gate wiring portion of the plurality of gate wiring portions which is connected to a gate conductive portion in the second transistor region.

18. The semiconductor device according to claim 1, wherein
the plurality of transistor regions comprise a first transistor region and a second transistor region with a larger area than the first transistor region, and
a resistance value of a wiring resistance portion of the plurality of wiring resistance portions which is provided in a gate wiring portion of the plurality of gate wiring portions which is connected to a gate conductive portion in the first transistor region is greater than a resistance value of a wiring resistance portion of the plurality of wiring resistance portions which is provided in a gate wiring portion of the plurality of gate wiring portions which is connected to a gate conductive portion in the second transistor region.

19. The semiconductor device according to claim 1, wherein an error in values of a CR time constant which is a product of a capacitance of a transistor region of the plurality of transistor regions and a resistance value of a wiring resistance portion of the plurality of wiring resistance portions which corresponds to the transistor region is within 20% in respective transistor regions of the plurality of transistor regions.

20. The semiconductor device according to claim 1, wherein the plurality of gate wiring portions comprise a gate wiring portion which is connected to one of two adjacent transistor regions and a gate wiring portion which is connected to another of the two adjacent transistor regions, which are provided between the two adjacent transistor regions among the plurality of transistor regions.
